(19) United States
(12) Patent Application Publication
(10) Pub. No.: US 2024/0315136 A1
(43) Pub. Date: Sep. 19, 2024

(54) PIEZOELECTRIC ACOUSTIC BIOSENSOR AND USES THEREFORE

(71) Applicant: UNIVERSITY OF SOUTH CAROLINA, COLUMBIA, SC (US)

(72) Inventors: SOURAV BANERJEE, IRMO, SC (US); DEBDYUTI MANDAL, CAYCE, SC (US)

(21) Appl. No.: 18/409,892

(22) Filed: Jan. 11, 2024

Related U.S. Application Data
(60) Provisional application No. 63/490,033, filed on Mar. 14, 2023.

(51) Int. Cl. H10N 30/30; G01H 11/08; G01N 29/02; H10N 30/80; H10N 30/853

(52) U.S. Cl. CPC H10N 30/302; G01H 11/08; G01N 29/022; H10N 30/802; H10N 30/8542

(57) ABSTRACT

Disclosed is an acoustic-based biosensing platform that can be utilized in point of care applications and can provide rapid results with both high sensitivity and high selectivity. The sensing platform includes a plurality of piezoelectric cantilevers conjugated with a specific binding member for a bioanalyte of interest. Upon excitation of an excitation cantilever, acoustic feature extraction from response signals can provide information with regard to the presence or quantity of a bioanalyte of interest.

### CROSS REFERENCE TO RELATED APPLICATION

This application claims filing benefit of U.S. Provisional patent application Ser. No. 63/490,033 having a filing date of Mar. 14, 2023, which is incorporated herein by reference for all purposes.

### FEDERAL RESEARCH STATEMENT

This invention was made with Government support under Grant No. 2017-67017-26167, awarded by the USDA/NIFA. The Government has certain rights in the invention.

### BACKGROUND

The early diagnosis of disease can enhance preventive measures, increase the curability of the disease, and reduce health care costs. For instance, the SARS-COV-2 outbreak in 2019 resulted in great devastation across the globe, at least partly due to the unavailability of diagnostic systems and vaccines for some time after the initial outbreak. Similarly, early detection of contamination, e.g., detection of algal boom in water springs, fungal contamination in agricultural produce, etc., can enable early response thereby saving agricultural output and preventing disease. Improved diagnostic devices and biosensors that can detect disease and pathogens in early stages of disease spread would be useful for early treatment as well as for accelerating development of treatments and preventatives, e.g., the vaccine development process.

There are various biosensing techniques in existence including optical-based, electrochemical-based, magnetic-based, and thermometric-based. Often, known systems require large and complicated lab setups, along with a trained professional to manage the equipment. Moreover, these techniques generally require extensive time and labor and include high chance of human error leading to false-positive and false-negative scenarios. For example, reverse transcription-polymerase chain reaction (RT-PCR) is a conventional diagnosis method, but this method is still not rapidly available nor affordable in many locations as RT-PCR requires a laboratory, multiple chemical reagents, and skilled personnel to carry out the procedure.

Various platforms have been developed to detect specific bio-analytes, but unfortunately, they generally suffer either low sensitivity or low specificity. As such, constant demand exists for biosensing platforms that can be utilized for early stage detections. The ideal biosensor would exhibit high sensitivity and high selectivity as well as affordability, reusability, ease of operation, faster analysis, and low bio-sample requirement. However, just to attain good sensitivity and good selectivity simultaneously in a single platform is a major challenge. For instance, sensors have been developed that can attain high sensitivity, but at the cost of poor specificity and selectivity. Good selectivity is necessary, however, as this indicates that the sensor will provide high response to the target analyte while limiting or ignoring recognition of other potential analytes and biomarkers present in the sample. Use of a biosensor that exhibits poor selectivity will lead to high numbers of false-positive and false-negative results, which will directly affect the specificity of the sensing platform irrespective of even ultra-high sensitivity.

Even in the case of sensors that can exhibit both high sensitivity and high selectivity (e.g., optical-based sensors), problems still exist. For instance optical-based biosensors, though very effective, still require highly skilled workers, massive and expensive apparatus, frequent maintenance, and a separate laboratory. Hence, pathogen detection via this route is simply not feasible for many remote areas and communities.

What is needed in the art is a Point-Of-Care (POC) biosensing platform that can be portable and can provide real time analysis at the onsite screening of a sample. A POC system that can provide high sensitivity, high selectivity, affordability, reusability, ease of operation, fast analysis, and low bio-sample requirement would be of great benefit to the art.

### SUMMARY

In one embodiment, disclosed is a biosensor that includes a plurality of piezoelectric cantilevers in acoustic communication with one another. One of the cantilevers is an excitation cantilever, and one or more of the cantilevers is/are response cantilevers. The response cantilever(s) include at a surface thereof a specific binding member for a biologically active analyte of interest.

Also disclosed is a system that includes a biosensor. The system can include an actuator in electrical communication with the excitation cantilever of a biosensor as described and a signal analyzer in electrical communication with the response cantilever(s).

Methods for determining the presence or quantity of a biologically active analyte are also disclosed. A method can include contacting a biosensor as described with a composition. The method can also include actuating the excitation cantilever and collecting and analyzing signals induced in the response cantilever(s) upon the actuation of the excitation cantilever. Through this analysis, the presence or quantity of the biologically active analyte in the composition can be determined.

### BRIEF DESCRIPTION OF THE FIGURES

A full and enabling disclosure of the present subject matter, including the best mode thereof to one of ordinary skill in the art, is set forth more particularly in the remainder of the specification, including reference to the accompanying figures in which:

FIG. 1 schematically illustrates one embodiment of an acoustic-based biosensor as described herein.

FIG. 2 schematically illustrates one response cantilever of an acoustic-based biosensor as described herein.

FIG. 3 illustrates a method of forming an acoustic-based biosensor as described herein.

FIG. 4 illustrates a 5-count tone burst signal (top) and a signal response (bottom) from a response cantilever of a sensor as described herein.

FIG. 5 illustrates a heat map of each cantilever beam (pristine) upon actuation as an excitation cantilever.

FIG. 6 provides a Fast Fourier Transform (FFT) spectral analysis over a frequency range of 1 to 7 MHz of response beams of a sensor as described herein.

FIG. 7 provides an FFT spectral analysis over a narrower frequency range of response beams of a sensor at 4.9 MHz excitation frequency.

FIG. 8A provides an FFT spectral analysis map of a single response beam (beam #8) of a sensor.

FIG. 8B provides FFT spectral analyses over two narrower frequency ranges of response beam #8 of a sensor.

FIG. 8C provides a 2D FFT plot of response beam #8 of a sensor at two different excitation frequencies (4.8 MHz and 2.9 MHz).

FIG. 8D provides the frequency domain simulation results for response beam #8 of a sensor at 2.9 MHz excitation frequency.

FIG. 9 schematically illustrates a portion of a response beam configured to capture an analyte of interest.

FIG. 10A compares superimposed signal comparison (top, a) and the FFT of frequency shifts (bottom, a1) for an initially formed and antigen coated response beam at 2.9 MHz excitation.

FIG. 10B compares superimposed signal comparison (top, b) and the FFT of frequency shifts (bottom, b1) for an initially formed and antigen coated response beam at 4.9 MHz excitation.

FIG. 11 provides 2D FFT signal comparisons of different response beams of a sensor and their frequency shifts between the initially-formed and antigen containing cantilever beams at 4.9 MHz excitation.

FIG. 12A provides a signal comparison (top, a) and the FFT shift (bottom, a1) for a response beam at an antigen baseline and upon PBS addition at 2.9 MHz excitation.

FIG. 12B provides a signal comparison (top, b) and the FFT shift (bottom, b1) for a response beam at an antigen baseline and upon PBS addition at 4.9 MHZ excitation.

FIG. 13 provides signal comparisons for antigen coated response beams and the sensing beams upon antibody capture.

FIG. 14 provides power spectral density (PSD) plot comparisons for response beam #2 (a), response beam #4 (b) and response beam #8 (c) for the antigen coated response beams and for the response beams upon antibody capture.

### DETAILED DESCRIPTION

Reference will now be made in detail to various embodiments of the disclosed subject matter, one or more examples of which are set forth below. Each embodiment is provided by way of explanation of the subject matter, not limitation thereof. In fact, it will be apparent to those skilled in the art that various modifications and variations may be made in the present disclosure without departing from the scope or spirit of the subject matter. For instance, features illustrated or described as part of one embodiment, may be used in another embodiment to yield a still further embodiment.

The present disclosure is generally directed to an acoustic-based biosensing platform that can be utilized in POC applications and can provide rapid results with both high sensitivity and high selectivity. The sensing platform can be utilized for a plurality of biomedical applications including, without limitation, applications based on antigen-antibody interactions, virus and anti-virus interactions, DNA or RNA hybridizations, protein synthesis, etc. Exemplary applications can include, without limitation, disease diagnostics, vaccine development, prophylactic/treatment development, and lab-on-chip technologies.

Disclosed POC biosensors can exhibit enhanced sensitivity as compared to previously known biosensors through a capability to capture extremely low concentrations of a target analytes and detection and identification thereof via an acoustic-based detection regime. Through use of an acoustic-electrical based design that incorporates a wide frequency coverage, extremely small microphysical changes of the sensors can be detected, which can lower the analyte detection limit and enhance sensitivity of the sensors in the detection of a targeted analyte even at very small concentrations. As such, detection of very small changes in analyte concentrations as well as detection of very low concentrations of analytes can be attained. Moreover, disclosed systems can provide results rapidly by use of a relatively small, inexpensive, and easy to use system. As such, disclosed biosensing systems can be provided as small, inexpensive, reusable, and portable POC biosensors that can provide both high selectivity and high sensitivity.

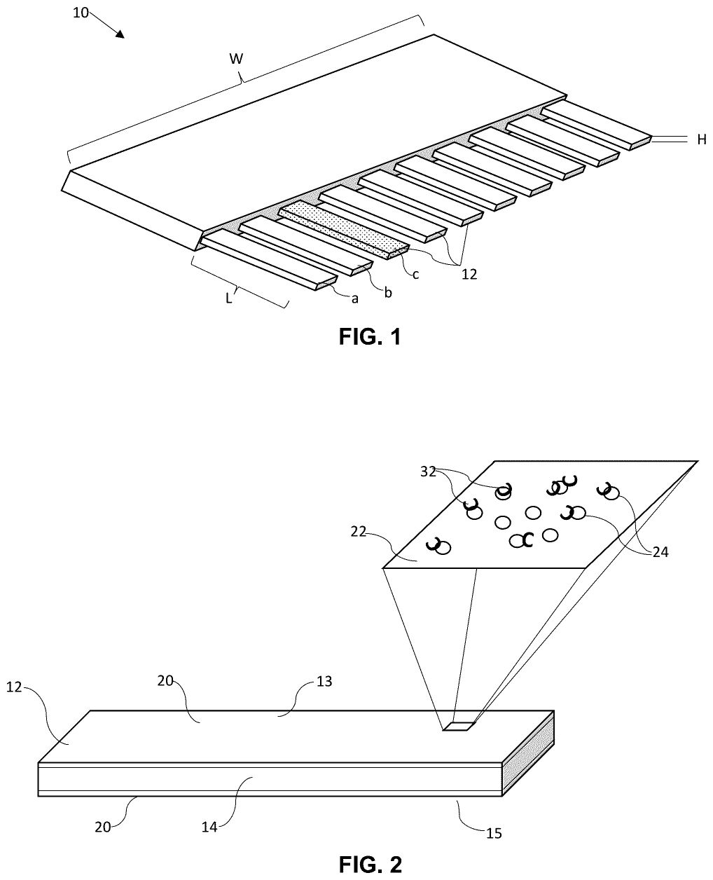

As illustrated in FIG. 1, a sensing mechanism 10 of an acoustic biosensor system incorporates a plurality of piezoelectric cantilevers 12 (also referred to herein as beams or cantilever beams) that can resonate to a central frequency. The cantilevers 12 are formed of a piezoelectric material. In general, all of the cantilevers 12 will be formed of the same piezoelectric material, e.g., formed from a single wafer of a piezoelectric material. This is not a requirement of a sensor, however, and in other embodiments, the cantilevers 12 can be formed of different piezoelectric materials, or combinations of identical and different piezoelectric materials.

In one embodiment, cantilevers 12 can include a relatively strong piezoelectric crystal of the 3 m class, e.g., lithium niobate, lithium tantalate, or natural tourmaline. In one embodiment, the cantilevers 12 can include a lithium niobate piezoelectric material, e.g., 128° YX cut lithium niobate.

The cantilevers 12 of a sensing mechanism 10 can differ from one another with regard to geometry and/or materials of formation. For instance, in the embodiment illustrated in FIG. 1, each of the individual cantilevers—a, b, c, etc. have a different length L, with each cantilever 12 increasing (or decreasing) in length with respect to an adjacent cantilever across the width W of the mechanism. In this particular embodiment, each of the plurality of cantilevers 12 is essentially identical in width W and height H as one another. This is not a requirement of a sensing system, and in other embodiments, the cantilevers of a system can vary with regard to one or more dimensions as well as with regard to overall shape. For example, one or more of the cantilevers 12 can define a curve in one or more dimensions. Individual cantilevers 12 can, for example, be in the shape of a cylindrical or ovoid rod, or include one or more flat surfaces in conjunction with a curved surface, e.g., a semi-circular rod.

The cantilevers 12 can optionally differ from one another with regard to a material of formation. For instance, individual cantilevers a, b, c, etc. can differ from one another with regard to the piezoelectric material of the cantilever, as mentioned previously. Optionally, one or more of the cantilevers a, b, c, etc. can include one or more coating layers, and the coating materials can differ from one another on different cantilevers. In one embodiment, individual cantilevers a, b, c, etc. can be coated with the same material as one another, but to a different coating depth.

Differences between individual cantilevers, whether geometric or formation material in nature, or a combination thereof, encourages non-identical response of the cantilevers during use. For instance, cantilevers that are otherwise identical but for a difference in cantilever length L can be used to exploit different wave modes in orthogonal directions and thereby provide different responses during use. Through analysis of the different responses of the cantilevers during a sensing protocol, selectivity of the biosensors can be enhanced. Moreover, through inclusion of a plurality of cantilevers that differ from one another in at least one aspect, a wide range of frequencies can be accessed by different cantilevers for sensing purposes. Through inclusion of a plurality of cantilevers that differ from one another in at least one aspect, each cantilever as well as any combination of cantilevers can be utilized over a wide range of frequencies to enhance and cross verify the sensitivity and selectivity of the biosensor.

During use, one of the cantilevers, e.g., cantilever c in the embodiment of FIG. 1, can be designated as an excitation cantilever. The other cantilevers 12, a, b, etc. can be designated as response cantilevers. The cantilevers are located in acoustic communication with one another such that upon actuation of the excitation cantilever c by use of an electronic signal to generate a corresponding excitation frequency, resonant oscillations in the adjacent cantilevers a, b, etc., will be induced, and corresponding response electrical signals generated.

To ensure suitable vibration and signaling, the cantilevers can generally have a length of about 10 mm or less, for instance, from about 2 mm to about 8 mm, or from about 3 mm to about 6 mm in some embodiments. Variation in a geometric dimension between adjacent cantilevers can generally be on the order of about 1 mm or less, such as from about 0.05 mm to about 5 mm, or from about 0.05 mm to about 2 mm in some embodiments. For instance, immediately adjacent cantilevers 12 can vary in length L from one another by a length about 0.05 mm to about 0.2 mm, or about 0.1 mm difference in length L in some embodiments. The cantilevers 12 will generally have a high aspect ratio, with the cantilever length L being at least 2 times the cantilever width W and height H. To ensure suitable acoustic communication between the cantilevers 12, each cantilever a, b, c, etc. can be separated from an adjacent neighboring cantilever by a distance of about 2 mm or less, such as from about 0.5 mm to about 1.5 mm, or about 1 mm in some embodiments.

As illustrated in FIG. 2, in some embodiments, one or more of the cantilevers 12 can include a base substrate 14 that includes a piezoelectric material and one or more coating layers 20 on the surface (e.g., the upper surface 13, both the upper 13 and lower 15 surfaces, or the entire cantilever surface). A coating layer 20 of a cantilever 12 can be provided to improve any aspect of the biosensor system including, without limitation improvement in formation, storage, electrical or mechanical characteristics, analysis characteristics, analyte capture characteristics, conjugation of additional materials to the surface, etc.

A coating layer, when present, can be continuous or discontinuous over a surface of a cantilever. For instance, a coating layer can cover about 95% or more, e.g., about 96% to 100% of the total surface area of the upper surface 13 of a cantilever 12, in which case it can be considered to be a continuous coating layer on the surface 13. Alternatively, a coating layer can be discontinuous, with the coating material present on a surface of the cantilever in the form of islands; straight, curved or randomly shaped lines that intersect or do not intersect; particles; a patterned material; a random material; etc.; or any combination thereof in which about 95% or less of the total surface area of the surface carries the coating material, e.g., from about 1% to about 90% of the total surface area of the surface.

By way of example, and without limitation, in one embodiment, a cantilever 12 can include a layer that can improve adhesion of one or more additional layers, e.g., a titanium, that can adhere to both the underlying piezoelectric substrate as well as an overlying layer that can provide an additional benefit to the device, e.g., conductivity, bioanalyte adhesion, etc. In one embodiment, an adhesion layer can be in the form of a self-assembled monolayer (SAM) 22 provided on a lower coating layer 20 and that includes a reactive functionality (e.g., aldehyde, carboxyl, amino, hydroxyl, or hydrazide, etc.) for conjugation of a further material to the surface of the cantilever 12.

In one embodiment, a cantilever 12 can include a coating layer 20 that can improve conductivity of the cantilever, e.g., a continuous or discontinuous layer of gold, or the like.

A material of a coating layer 20 can in one embodiment provide use as a conjugation material for directly or indirectly adhering/bonding a specific binding member 32 to a cantilever 12. During use, a specific binding member 32 can bind a biologically active analyte of interest (also referred to herein as a bioanalyte) as may be present in a sample to be tested. A conductive material can be beneficial in such an embodiment, as a conductive material can be utilized both for improving conductivity of a cantilever as well as for direct or indirect conjugation of a specific binding member.

In one embodiment, a coating material can include particles 24, e.g., micro- or nanoparticles that can be directly or indirectly conjugated with a specific binding member 32 for a targeted bioanalyte. A particulate material, e.g., nanoparticles 24, can provide a high surface area for analyte conjugation as well as increase orientational freedom, both of which can increase the concentration/orientation of specific binding members at the cantilever surface and increase the probability of capturing the targeted bioanalyte, even at very low concentrations, and thereby increase sensitivity of a system.

Particles 24 as may be conjugated to a cantilever 12 and that can directly or indirectly carry a specific binding member 32 can include naturally occurring particles as well as synthetic particles. By way of example, natural particles, such as nuclei, mycoplasma, plasmids, plastids, polysaccharides (e.g., agarose), silica, glass, cellulose-based particles, and the like, can be used. Conductive nanoparticles, e.g., gold nanoparticles, can be utilized that can improve the electron transfer rate of a piezoelectric cantilever as well as carry a specific binding member. Further, synthetic particles may also be utilized such as polymeric particles that incorporate a synthetic polymer. Although any polymeric particle may be used, polymeric particles are typically formed from polystyrene, butadiene styrenes, styreneacrylic-vinyl terpolymer, polymethylmethacrylate, polyethylmethacrylate, styrene-maleic anhydride copolymer, polyvinyl acetate, polyvinylpyridine, polydivinylbenzene, polybutyleneterephthalate, acrylonitrile, vinylchloride-acrylates, and the like. For conjugation to a specific binding member, a particle can include or be derivatized to include reactive functionalization such as, and without limitation to, aldehyde, carboxyl, amino, hydroxyl, or hydrazide functionalization.

Each cantilever 12 can be conjugated with a specific binding member 32 of a bioanalyte of interest. Specific binding members generally refer to a member of a specific binding pair, i.e., two different molecules where one of the molecules chemically and/or physically binds to the second molecule. For instance, specific binding members can include a monoclonal or polyclonal antibody or a fragment thereof, a natural or recombinant protein or a mixture(s) or fragment(s) thereof, a polynucleotide, etc.

In one embodiment, a specific binding pair can include an antibody and its antigen. By way of example, a cantilever 12 can be directly or indirectly conjugated with a SARSCoV-2 antigen (e.g., a spike protein or fragment thereof) that can specifically bind COVID-19 antibodies. Of course, a system is not limited to such, and any specific binding pair is encompassed herein. Other common specific binding pairs include but are not limited to, biotin and avidin, biotin and streptavidin, antibody-binding proteins (such as protein A or G) and antibodies, carbohydrates and lectins, complementary nucleotide sequences (including label and capture nucleic acid sequences used in DNA hybridization assays to detect a target nucleic acid sequence), complementary peptide sequences including those formed by recombinant methods, effector and receptor molecules, hormone and hormone binding protein, enzyme cofactors and enzymes, enzyme inhibitors and enzymes, and the like. Furthermore, specific binding pairs can include members that are analogs of the original specific binding member. For example, a derivative or fragment of the analyte, i.e., an analyte-analog, can be used so long as it has at least one epitope in common with the analyte.

During use, the sensing mechanism 10 can be contacted with a sample suspected of containing the analyte of interest. As utilized, herein, the term “sample” generally refers to a material suspected of containing an biologically active material of interest. For example, a sample may be obtained or derived from a biological source, such as a physiological fluid, including, blood, interstitial fluid, saliva, ocular lens fluid, cerebral spinal fluid, sweat, urine, milk, ascites fluid, mucous, synovial fluid, peritoneal fluid, vaginal fluid, amniotic fluid, and so forth. Besides physiological fluids, other samples may be used such as those derived from an environmental source including, without limitation, water, food products, soil, etc., for the performance of environmental or food production examination. A sample may be used directly as obtained from a source or following a pretreatment to modify the character of the sample. For example, such pretreatment may include preparing plasma from blood, diluting viscous fluids, and so forth. Methods of pretreatment may also involve filtration, precipitation, dilution, distillation, mixing, concentration, inactivation of interfering components, the addition of reagents, etc. Moreover, it may also be beneficial to modify a solid test sample to form a liquid medium, to release the biologically active agent into a liquid medium for interaction with the biosensor.

A biosensor can be contacted with a sample according to any suitable approach including, without limitation, flowing a sample past the biosensor such that the sample contacts the cantilevers 12 of the biosensor, immersing the biosensor cantilevers 12 in a sample, applying the sample to the cantilevers, etc.

A biosensor system can include a sensing mechanism 10 in electrical communication with a signal processing system as is generally known in the art. More specifically, the excitation cantilever c of a mechanism 10 can be in electrical communication with a signal processing system and configured to receive an actuation signal and, upon receipt of the signal, be excited to vibrate at a high frequency. In one embodiment, the excitation frequency can be an ultrasonic frequency. For instance, the excitation frequency of the excitation cantilever c can be about 20 kHz or greater, such as about 50 kHz or greater, such as about 100 kHz or greater. In some embodiments, the excitation frequency can be from about 100 kHz to about 10 MHz, such as from about 200 kHz to about 8 MHZ, or about 500 kHz to about 7 MHz, in some embodiments.

The particular form of the excitation signal is not particularly limited. In one embodiment, the excitation signal can be a 5-count tone burst signal. In such an embodiment, the tone burst signal can be generated using a simple sinusoidal wave coupled with the Hanning window function. Equation 1 describes the generic equation for a tone burst signal as may be used for the signal excitation.

$$X ( t ) = sin ( N * 2 π ft ) * {e}^{{[ - \frac{( t - {T}_{0} )}{\frac{{T}_{0}}{2}} ]}^{2}} \qquad ( 1 )$$

in which, Nis the number of cycles, f is the central frequency, t is the time and T₀ refers to the time-period of the burst signal. This type of signal is widely used in the field of structural health monitoring for non-destructive evaluation methods. The excited tone burst signal can be electrically transmitted through the input terminal (i.e., the terminal associated with excitation cantilever c). Through electromechanical transduction, the input electrical energy is converted to mechanical stresses, and the stress wave propagated through the cantilever in form of wave packets. These wave packets then interact with the complete geometry of the cantilever and the response cantilevers a, b, etc. can respond with their unique vibration signature. Through inclusion of a plurality of response cantilevers that differ from one another in at least one aspect, the different cantilevers behave as different sensors in capture of the signal response.

The signal captured by the signal processing system can then be analyzed using one or more of any number of multiple acoustic feature extraction tools as are known in the art for the quantification of detection. In one embodiment, multiple acoustic feature extractions can be performed on the response signals from all response cantilever beams including, without limitation, frequency shift analysis, spectral energy analysis, time-domain tone burst acoustic signal analysis, etc. Analysis of the response signals can provide information to enable detection and, in some embodiments, quantification of the targeted bioanalyte present within a sample.

Disclosed acoustic-based biosensors can provide enhanced sensitivity to the extremely small concentration or mass of a bioanalyte due to the large frequency coverage possible with the sensors. In addition, the advanced technology of multiple signal feature extraction covers an ample area in which different biologically active agents, even in extremely small concentration, have improved likelihood of capture and detection through use of the acoustic feature extraction methodology and thus, disclosed sensors can exhibit increased sensitivity as compared to previously known biosensors.

The present disclosure may be better understood with reference to the Examples, set forth below.

### Examples

### Chemicals and Reagents

The Recombinant SARS-COV-2 Spike Protein and the Polyclonal Rabbit antibody against SARS-COV-2 (COVID-19) Spike Protein Subunit 2 (S2F) Protein were purchased from RayBiotech. Monoclonal Antibodies to Cancer Antigen 125 (CA-125), ovarian cancer were purchased from Meridian Life Science, Inc. N-(3-dimethylaminopropyl)-N′-ethylcarbodiimide hydrochloride (EDC), N-hydroxysuccinimide (NHS), ethanolamine, thiourea, phosphate buffer saline (PBS), and deionized (DI) water were purchased from Sigma Aldrich. Polyethylene glycol (PEG)-carboxyl functionalized 10 nm Biopure Gold nanospheres were purchased from NanoComposix. 128° YX-cut lithium niobate piezoelectric wafers of 350 μm thickness were purchased from Custom Glass and Optics, USA.

### Fabrication of the Lithium Niobate Cantilevers

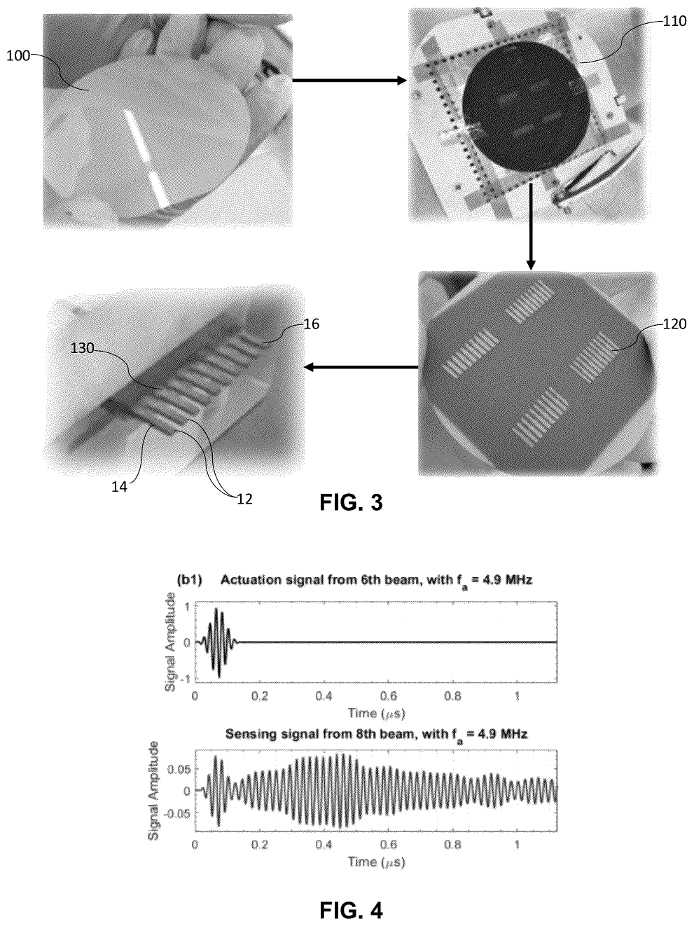

Lithium niobate cantilevers were fabricated using metal deposition and laser cutting processes as illustrated in FIG. 3. The as-provided wafers 100 were aligned with a 3D printed mask film 110 and then deposited with titanium and gold layers on both the upper and lower surfaces. The deposition process was performed using Denton E-Beam Evaporator System from the Institute for Electronics and Nanotechnology (IEN) at Georgia Institute of Technology. An approximately 100 nm thick titanium layer was deposited followed by a gold layer of 2 microns on both the top and bottom surfaces. The mask was removed 120 and the metal-deposited piezoelectric wafer was then cut using the Optec Femtosecond Laser Micro-Machining system which utilizes ultra-short laser pulses for the photo-based ablation. Each sensor 130 cut from the wafer included 10 cantilevers 12 at a progressive length with the longest beam 14 of 5 mm length and the shortest beam 16 of 4.1 mm with a progression of 0.1 mm length for each successive beam. The gap between adjacent beams and the width of each beam was constant at 1 mm. One side of the chip was then laser engraved to electrically isolate the individual beams and the other side was left for electrical grounding purpose. The beams were electrically connected using thin conductive copper strips. Further, they were covered and insulated using the Kapton tapes.

### Acoustic Measurements

All acoustic measurements were carried out using a National Instruments™ PXI-1036 system (NI). The NI system was equipped with a PXI-5412 100 megasamples per second (MS/s) Arbitrary Waveform Generator, 14-bit 8 MB PXI-5105 8-ch 60 MS/s Digitizer with 16 MB Onboard Memory, PXI-2570 40 Channel Form C Relay Module, Windows 7 32-Bit for PXI Embedded Controllers, and PXI-8102 Celeron T3100 1.9 GHz Controller. The NI system uses a custom developed integrated LabView software for the data acquisition and as a result, a Graphical User Interface (GUI) was designed and developed for easy and quick measurements of the ultrasound signals. An electrical junction box having 10 channels was also fabricated where the subminiature version B (SMB) type connectors were connected to the NI system.

FIG. 4 graphically illustrates the 5-count tone burst signal excited at the frequency at 700 KHz at excitation/actuator beam 6 and the sensing response from the response beam 4. As can be seen, in addition to a crosstalk, multiple new wave packets are generated through wave dispersion. By virtue of different lengths of response beams and variable distance from the actuator beam, different response beams demonstrate different dispersive responses. These dispersed waveforms can carry information concerning the modal activation of the sensory beams. Such information can be decoded by acoustic feature extraction methods to provide information concerning the biochemical content of the sensor.

Excitation of Pristine Cantilever Beams with a Tone Burst Signal

An input Burst signal was provided to a terminal associated with a selected cantilever beam as the selected actuator or exciter beam. Wave signals were collected from the terminals associated with respective response beams. Signals were collected at different excitation frequencies, 700 KHz-5.5 MHz at an interval of 200 kHz resulting in 49 frequencies. For each beam examined as an exciter, 49 sets of data were collected from 9 beams marked as the sensing beams. Thus, when an i-th beam was used as an actuator total of 49×9=401 wave signals were collected from one set of experiments automatically. This was repeated 3 times such that 10×3=30 sets of signals were collected to perform an analysis, in which 10 represents the total number of beams of the sensor used (in turn) as exciter (E).

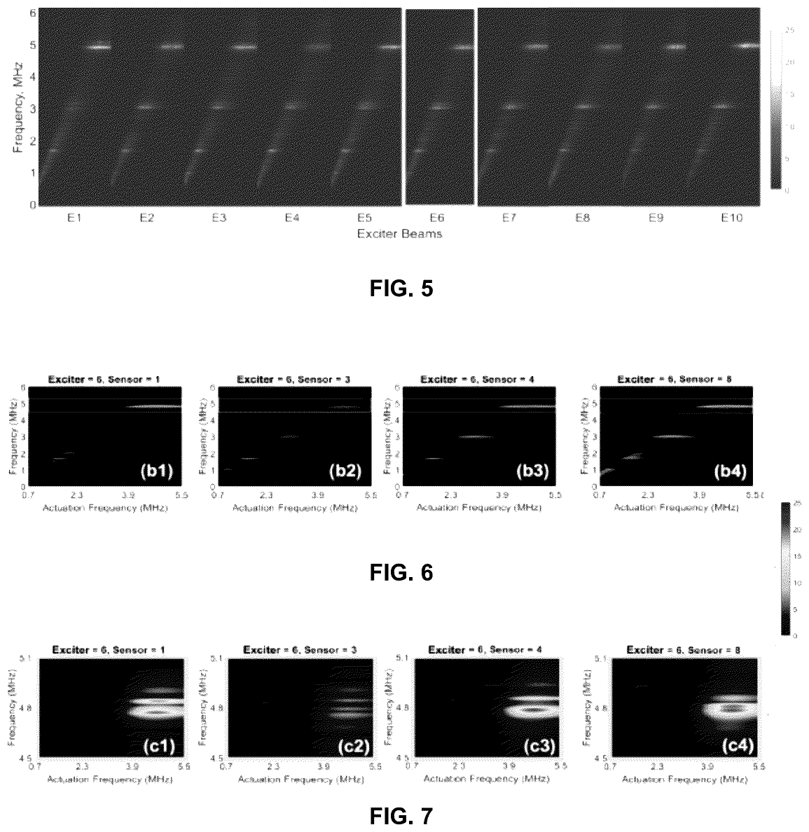

Ei in FIG. 5 shows the i-th beam used as an actuator when i has values between 1-10. FIG. 5 shows the heat map of the average frequency contents of the acquired sensor signals plotted as an augmented surface frequency spectrum using Fast Fourier Transform (FFT). Here, 49×9=401 FFT signals were augmented side by side for each beam as exciter. A general trend emerged from the plot showing that a significantly higher frequency response was obtained near ˜4.9 MHz and ˜2.9 MHz. It was also observed that when the 6th beam (E6) was the exciter the response signals from the other beams were promising with comparatively higher amplitude. Hence, the 6th beam was chosen as an exciter to perform other experiments and analysis reported herein.

2D FFT of the signals collected from beam 1, beam 3, beam 4, and beam 8 are shown in FIG. 6 over the range of 700 KHz to 5.5 MHz excitation frequencies. A frequency range around the ˜4.9 MHz was found to provide the peak responses from all the beams that were used as sensors. FIG. 7 shows a more detailed FFT spectrum in the frequency range between 4.5-5.1 MHz. Higher amplitudes were detected with multiple acoustic frequency lobes in this range for all the sensing beams. As seen in FIG. 6 and FIG. 7, both frequency ranges had a comparable signal amplitude of approximately 17 mV and 20 mV, respectively. It was evident that beam 8 had a maximum resonance at those frequencies.

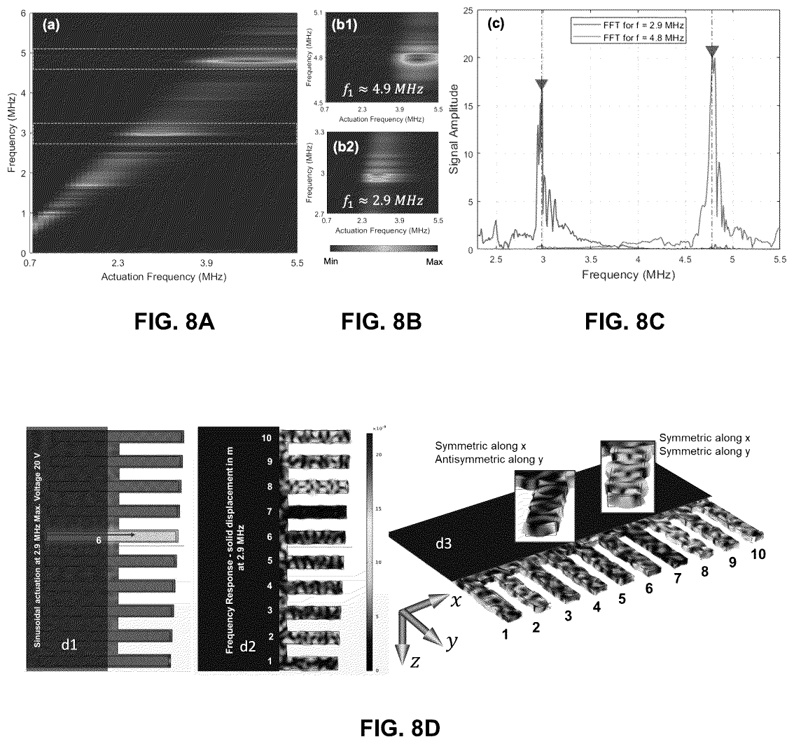

The spectral analysis of the signals collected from beam 8 (arbitrarily chosen) showed that there were multiple spectral peaks present in the frequency range. Major spectral peaks were observed around 800 kHz-1.2 MHz, 1.8 MHz, 2.9 MHz, and 4.9 MHz. FIG. 8A and FIG. 8B provide the FFT spectral map of beam 8 as a sensor. FIG. 8C provides the 2D FFT plot of beam 8 at excitation frequencies of 2.9 MHz and 4.8 MHz. FIG. 8D provides the frequency domain simulation result at 2.9 MHz only (4.9 MHz is not shown, however, simulations at all frequencies between 700 KHz-5.5 MHz at an interval of 200 kHz were performed). FIG. 8D at d1 shows the input electric potential and actuation voltage of 20 V with sinusoidal actuation frequency 2.9 MHz the was applied to the 6th terminal. FIG. 8 at d2 shows the top view (x-y plane) of the total solid displacement field in each beam. FIG. 8D at d3 shows the 3D view of the total sold displacement field for each beam with an inset showing zoom views of the displacement field for beam 5 and beam 8. Beam 8 had symmetric wave mode along both the x and y axes, whereas beam 5 had symmetric propagating mode along the x axis and antisymmetric wave mode along the y-axis. This illustrates a reason for implementing multiple beams with multiple lengths to exploit two different wave modes in two orthogonal directions such that the responses could be non-identical for each beam and selectivity could be enhanced. Although not shown, similar but higher frequency wave modes in the other beams were evident at 4.9 MHz.

### Surface Functionalization of the Cantilevers

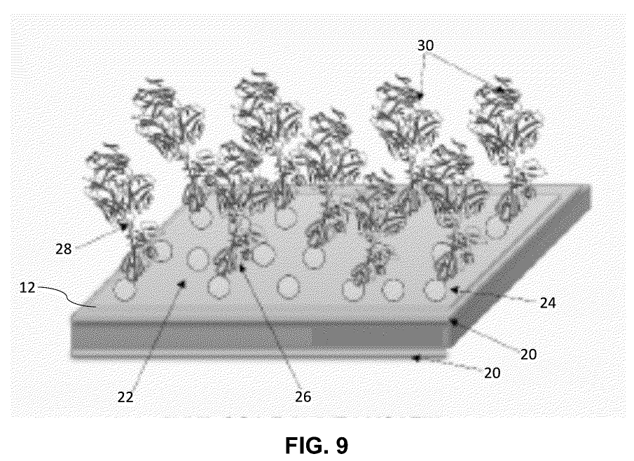

With reference to FIG. 9, which illustrates a portion of a single functionalized response cantilever 12, the cantilevers of a sensor were washed multiple times using ethanol and DI water and dried with nitrogen gas before the functionalization process. The gold surface 20 of each of the response cantilever beams were coated with a self-assembled monolayer (SAM) 22 by addition of 100 mM of thiourea solution in DI water overnight. The cantilever beams were then rinsed with ethanol and DI water to remove excess thiourea. A layer of gold nanoparticles 24 was then deposited on top of the SAM coated cantilever beams. Specifically, carboxyl functionalized PEG encapsulated gold nanoparticles 24 having 10 nm diameter were added on top of the SAM 22 coated cantilevers 12 and incubated for 10-12 hours. The nanoparticles 24 were then surface activated by the addition of 75 mM EDC followed by 50 mM NHS for the covalent binding of the detection antibodies to the gold nanoparticles.

### Immobilization of the SARS-COV-2 Spike Protein

Following addition of the nanoparticles 24, the sensor was rinsed using PBS (pH 7.4) and dried with nitrogen gas to remove excess nanoparticles. Following, 5 μl of 0.5 mg/ml Rabbit antibody against SARS-COV-2 spike RBD protein subunit 2 (S2F) (26) were added to the surface activated gold nanoparticles and incubated for 4 hours at 4° C. The sensor was rinsed with PBS and then incubated with 5 μl of recombinant SARS-COV-2 Spike Protein, S2 Subunit (28), for 6-8 hours at 4° C. The sensor surface was then blocked by adding 1 μl of ethanolamine to the sensor surface.

### Capture of SARS-COV-2 Antibodies

The cantilevers sensor was then tested for capture of polyclonal SARS-CoV-2 antibodies (30). The sensor surface was rinsed with PBS and contacted with 5 μl solution including 0.5 mg/ml polyclonal SARS-COV-2 antibodies. Following, acoustic readings were obtained to confirm capture of the targeted antibodies.

For all SARS-COV-2 experiments, beam 6 (terminal 6) was not coated with any of the bio/chemical layers and was marked as the exciter beam and other beams were utilized as response beams.

The experiments were carried out in 3 stages. Stage 1: After the response beams were functionalized with the Rabbit antibody against SARS-COV-2 spike RBD protein subunit 2 (S2F) (26) and prior to contact with the recombinant SARS-COV-2 Spike Protein, S2 Subunit (28), an initial set of data was collected in which the actuator beam was excited and the sensing beams were used as sensors. A 5-count tone burst signal with a single cycle was triggered throughout the experiments with the frequency ranging from 700 kHz to 5.5 MHz at an interval of 200 kHz at each interval. It was observed that the signal responses were not significant and were below noise level for the case of the shortest terminal (beam 1) and the longest terminal (beam 10), possibly due to manufacturing defects. Hence, they were omitted from all the following experiments and analyses.

Stage 2: Next the response beams were functionalized with SARS-COV-2 Spike Protein, S2 Subunit (28) as described above. Following a similar protocol as for the pristine data set was carried out and a second set of baseline data were collected to measure and quantify the effect of the addition of antigens on the functionalized layer.

Stage 3: Finally, SARS-COV-2 antibodies (30) were attached to the beam arrays. Again, a data set was collected from each response beam except for beams 1 and 10.

All the acoustic measurements were carried out at a sample rate of 40 MS/s and 3000 data points were collected for each measurement. Each set of experiments was repeated three times and all data were curated.

### Tone Burst Signal: Excitation and Sensing

Per the above description, beam number 6 was the excitation beam throughout the experimental procedures with a 5-count tone burst signal. As the substrate was a piezoelectric material made of 128° YX cut lithium niobate, it generated guided waves that propagated inside the wafer, including the sensor body and all of the beams that were laser cut with unique sizes. The experiments were repeated with different input excitation frequency f ranging between 700 kHz and 5 MHz at an interval of 200 kHz. The piezoelectric responses corresponding to each different excitation frequency were captured and monitored at the different sensing beams.

### Signal Analysis of the SARS-COV-2 Antigen Baseline

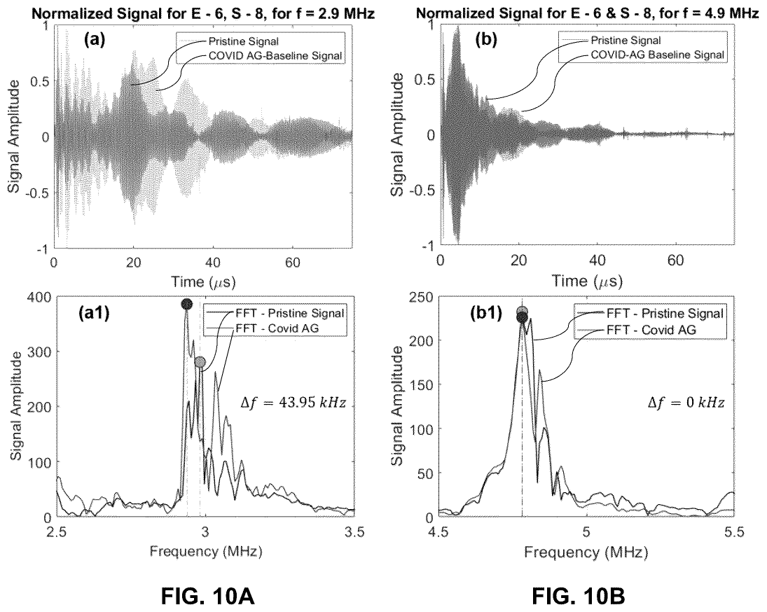

Signal analyses were performed with all the sensor beams coated with the ‘baseline’ COVID-19 antigens (Stage 2) and were compared with the initial state results (Stage 1). Although all the beams were tested, beam 8 is presented herein because of its strong response and higher sensitivity at the actuation signal frequencies. FIG. 10A and FIG. 10B show the frequency spectrum of the signals acquired from the initial state and following the antigens coatings. Maximum amplitudes were observed near 2.9 MHz and 4.9 MHz.

Detailed spectral variations were investigated and compared for the initial and the antigen coated configurations. Terminal 3, 4, and 5, located on the left side of beam 6, provided a negative frequency shift of the peak frequency around the vicinity of 4.9 MHZ. About −87.8 kHz, −73.24 kHz, and −7.3 kHz, respectively. The sensor beams on the right side of beam 6, namely beam 7, 8, and 9, displayed a positive or no frequency shift of the peak frequency. Approximately, 80.56 kHz, 0 kHz and 36.62 kHz, respectively.

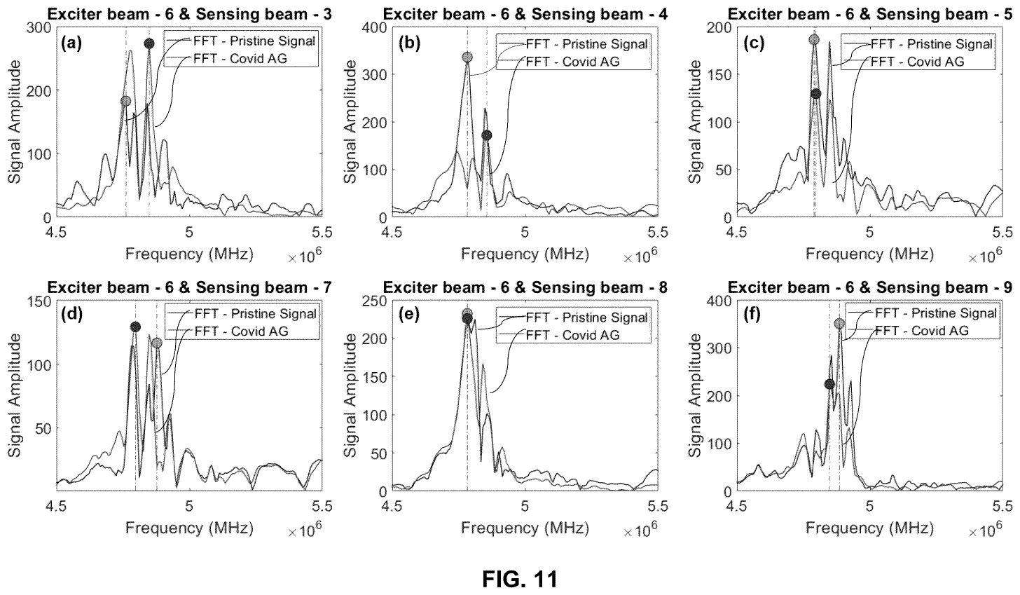

It was evident that most of the beams demonstrated promising responses in the frequency domain with significant variation of their respective peak frequency content. Such shifts at the range of kHz are substantial in terms of sensitivity for micro/nano scalar detection. It was noted that the beam 8 response had no shift of peak frequency between Stage 1 and Stage 2 tests. FIG. 11 shows the frequency spectrum of the acquired signals at beams 3, 4, 5, 7, 8, and 9 and their respective variations between the pristine and the antigens ‘baseline’ cases.

### Detection of SARS-COV-2 Antibodies Using FFT Signal Analysis

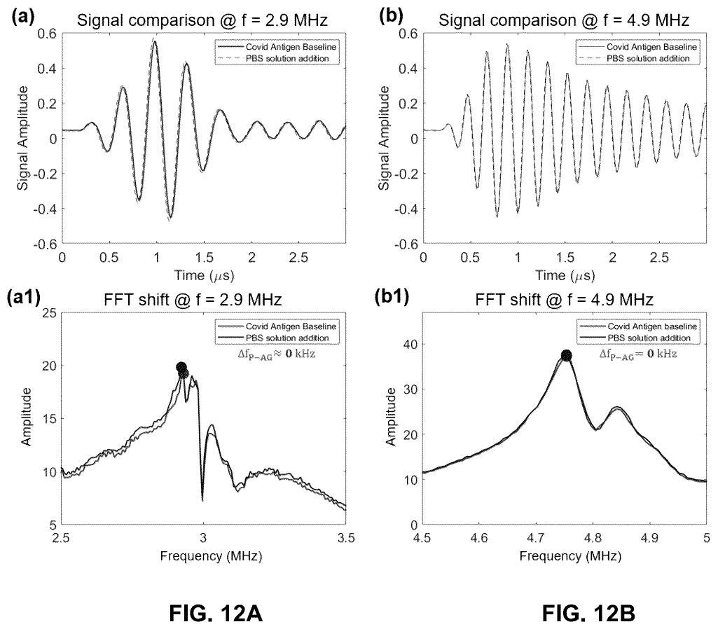

The sensor was first validated for the selectivity before the detection of the antibodies to check for cross-reactivity. The purpose of this step was to inspect if the sensor was affected due to non-target binding or mass addition. An exact volume of the solvent (only PBS) was appended on the sensing platform. The resulted signals with actuation frequencies 2.9 and 4.9 MHz were captured and analyzed for all the beams. FIG. 12A and FIG. 12B show the ultrasonic signals for sensing beam 8 in both time domain (FIG. 12A (top, a), FIG. 12B (top, b)) and frequency domain (FIG. 12A (bottom, a1), FIG. 12B (bottom, b1)) acquired from terminal 8 after the addition of PBS on the sensing platform previously functionalized with the antigen.

The sensing signals were captured before and after the addition of PBS solution. FIG. 12A and FIG. 12B provides the superimposed signals at excitation of 2.9 and 4.9 MHZ, respectively for sensing beam 8. As shown, the signal received after the addition of PBS depicted negligible changes in the time domain signals and almost no change in the peak frequency response. This satisfies the selectivity with respect to the case of non-target binding responses due to the mass loading.

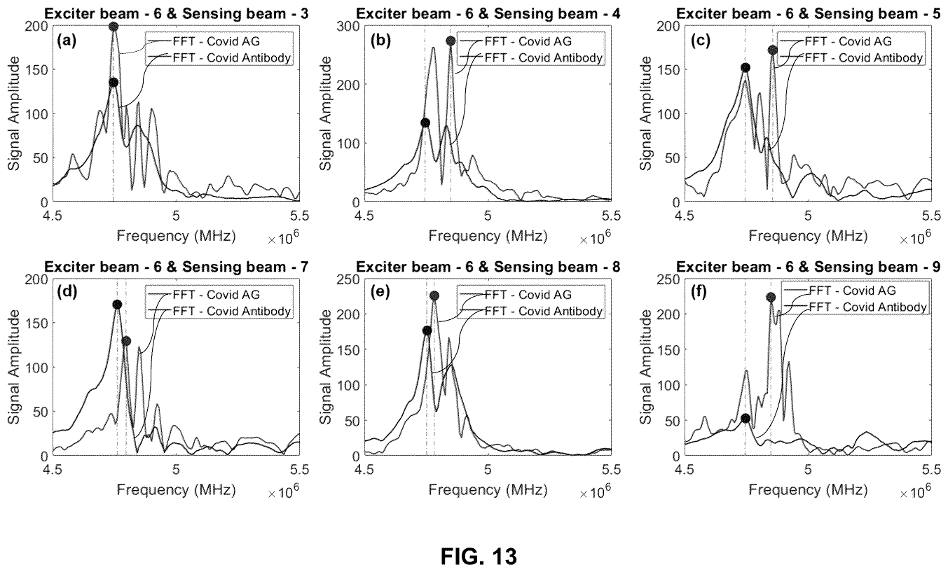

Following, the antibodies were added and beam 6 was excited again. It was ensured that all sensing beams were sensed at different frequencies. The FFT signals from all the beams displayed positive frequency shifts upon the addition of the SARS-COV-2 antibodies. The SARS-COV-2 antibodies were placed on all the beams and signals were acquired from the terminals. The signal comparisons prior to and following antibody capture for beams 3, 4, 5, 7, 8, and 9 are shown in FIG. 13. It was clearly evident that after the addition of the COVID-19 antibodies, all signals at all the terminals made a frequency shift. It was observed that the addition of the COVID-19 antibodies to the sensing platform induced the longer sensing beams to represent higher amplitudes of the FFT waveform signals and vice-versa for the shorter beams corresponding to a particular actuation frequency. However, the frequency shifts varied for different sensing beams at different excitation frequencies.

Overall, it was clearly witnessed that all sensing beams showed an excellent response to the addition of the antibodies. The detection ranges were in kilohertz (up to a couple of hundreds) which covers a wider spectrum for the frequency shift-based detection for the diagnosing purpose, indicating to a highly sensitive sensing platform even to the slightest biophysical changes.

### Power Spectral Density (PSD)

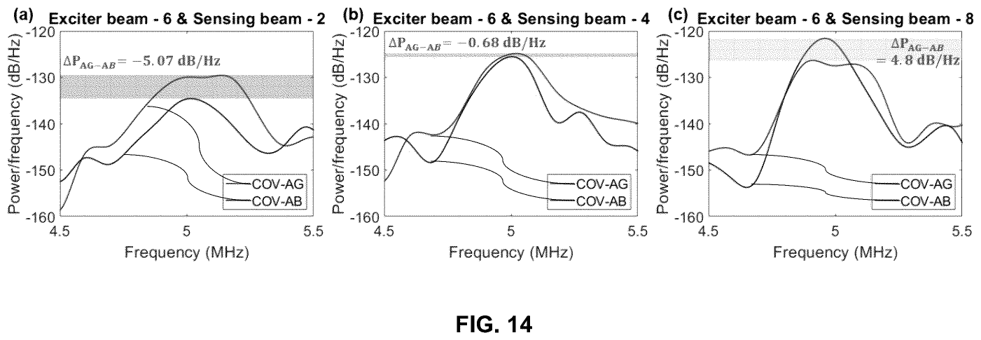

Power Spectral Densities (PSD) were estimated from all signals when beam 6 was used as an exciter. The PSD constitutes the total signal power contribution from each frequency component of a particular signal. PSD is a frequency response of any signal irrespective of periodic or random signal data and it signifies the average power distribution as a function of frequency. Welch's power spectral density estimation was used. FIG. 14 shows the PSD of the signals Collected before and after the addition of the antibodies from the terminal's sensors 2, 4 and 8, respectively.

From PSD analysis, near 4.9 MHz a trend was observed. It was seen that the amplitude of the power/frequency value in dB/Hz increased with the increasing length of the sensor beams when the COVID-19 antibodies were added to the sensor surface. For example, sensor 2 being one of the shorter beams showed a power/frequency value of approximately-135 dB/Hz. Sensor 4 had a value of −128 dB/Hz. But the best response was exhibited by sensor 8 having an amplitude of −122 dB/Hz. Interestingly, PSD for all the sensors with and without COVID-19 antibodies had a difference. These differences were higher and negative for the shorter beams but with a gradual reduction of the peak difference, larger beams had a positive difference. Irrespective of the changes, all beams collectively and individually detected the presence of COVID-19 antibodies.

These and other modifications and variations to the present invention may be practiced by those of ordinary skill in the art, without departing from the spirit and scope of the present invention, which is more particularly set forth in the appended claims. In addition, it should be understood that aspects of the various embodiments may be interchanged both in whole or in part. Furthermore, those of ordinary skill in the art will appreciate that the foregoing description is by way of example only, and is not intended to limit the invention so further described in such appended claims.

What is claimed:

1. A biosensor comprising a plurality of piezoelectric cantilevers in acoustic communication with one another, a first cantilever of the plurality being an excitation cantilever and a second cantilever of the plurality being a response cantilever, the second cantilever comprising a specific binding member for a biologically active analyte conjugated to a surface thereof.

2. The biosensor of claim 1, the plurality of cantilevers comprising one or more additional response cantilevers, wherein the response cantilevers differ from one another.

3. The biosensor of claim 1, wherein the response cantilevers differ from one another with regard to cantilever length.

4. The biosensor of claim 1, wherein each of the plurality of piezoelectric cantilevers comprise a piezoelectric crystal of the 3 m class.

5. The biosensor of claim 4, wherein each of the plurality of piezoelectric cantilevers comprises a lithium niobate.

6. The biosensor of claim 1, wherein one or more of the plurality of cantilevers comprises a coating layer.

7. The biosensor of claim 6, the coating layer comprising an adhesion layer, a conductive layer, or a combination thereof.

8. The biosensor of claim 6, wherein the coating layer comprises a particle.

9. The biosensor of claim 8, wherein the specific binding member is directly or indirectly conjugated to the particle.

10. The biosensor of claim 1, wherein the specific binding member comprises a monoclonal or polyclonal antibody or fragment thereof, a natural or recombinant protein or fragment thereof, or a polynucleotide.

11. A system comprising:
the biosensor of claim 1;
an actuator in electrical communication with the excitation cantilever; and
a signal analyzer in electrical communication with the response cantilever.

12. The system of claim 11, wherein the actuator and the signal analyzer are components of a single signal processing system.

13. A method for determining the presence or quantity of a biologically active analyte in a sample, the method comprising:
contacting a biosensor with the sample, the biosensor comprising a plurality of piezoelectric cantilevers in acoustic communication with one another, a first cantilever of the plurality being an excitation cantilever and a second cantilever of the plurality being a response cantilever, the second cantilever comprising a specific binding member conjugated to a surface thereof, the specific binding member exhibiting a specific binding with the biologically active analyte;
providing an excitation signal to the excitation cantilever and thereby generating a vibration in the excitation cantilever; and
analyzing signals induced in the response cantilever in response to the vibration of the excitation cantilever, the analysis providing a determination of the presence or quantity of the biologically active analyte in the sample.

14. The method of claim 13, wherein the vibration in the excitation cantilever is at an ultrasonic frequency.

15. The method of claim 13, wherein the excitation signal is a 5-count tone burst signal.

16. The method of claim 13, analysis comprising multiple acoustic feature extractions.

17. The method of claim 16, the acoustic feature extractions comprising frequency shift analysis, spectral energy analysis, or time-domain tone burst acoustic signal analysis.

18. The method of claim 16, wherein the sample is derived from a biological source.

19. The method of claim 18, wherein the biological source comprises a physiological fluid.

20. The method of claim 16, wherein the sample is derived from an environmental source.
